(19) United States
(12) Patent Application Publication
(10) Pub. No.: US 2025/0368532 A1
(43) Pub. Date: Dec. 4, 2025

(54) PIEZOELECTRIC MATERIAL WITH PEROVSKITE STRUCTURE FOR HIGH OPERATING TEMPERATURES AND ITS MANUFACTURING PROCESS

(71) Applicant: PI CERAMIC GMBH, Lederhose (DE)

(72) Inventors: Silvio GABLENZ, Halle (Dölau) (DE); Michael OERTEL, Großpürschütz (DE); Timo SCHOLEHWAR, Gera (DE)

(21) Appl. No.: 18/876,776

(22) PCT Filed: May 31, 2023
(86) PCT No.: PCT/EP2023/064565

§ 371 Date: Dec. 19, 2024

(30) Foreign Application Priority Data
Jun. 23, 2022 (DE) 10 2022 115 666.4

(51) Int. Cl. C01G 49/00

(52) U.S. Cl. CPC C01G 49/0018; C01P 2002/34; C01P 2002/52; C01P 2004/02

(57) ABSTRACT

Provided is a compound with a perovskite structure, which has the basic composition AgₓBi_{y}M_{z}FeᵥN_{w}O₃, wherein x+y+z=0.9 to 1.1 and v+w=0.9 to 1.1, wherein M is selected from Pb and/or Ba, and wherein N is selected from Ti and/or Zr, and which can be used as a basis for the production of perovskite materials and functional ceramics with piezoelectric properties at high temperatures. Furthermore, a process for the production of a material with piezoelectric functionality is provided, which guarantees a consistent and high product quality and at the same time offers advantages in terms of safety and enables production without the use of organic solvents. Furthermore, a piezoelectric device is provided which comprises the aforementioned perovskite material or the compound with a perovskite structure.

### CROSS REFERENCE TO RELATED APPLICATIONS

This application is a 371 U.S. National Phase of International Application No. PCT/EP2023/064565, filed on May 31, 2023, which claims priority to German Patent Application No. 10 2022 115 666.4, filed Jun. 23, 2022. The entire disclosures of the above applications are incorporated herein by reference.

### BACKGROUND

### Technical Field

The present invention relates to a composition with a perovskite structure which can be used as a starting material for the production of perovskite functional ceramics with piezoelectric properties at high temperatures.

In addition, a method of manufacturing a material comprising the specified composition and a piezoelectric device comprising the material are described.

### Related Art

Piezoelectric materials are characterized in that their electrical polarization changes as a result of mechanical action (piezoelectric effect) or that the application of an electrical voltage causes a change in the dimensions of the material or its mechanical movement (inverse piezoelectric effect). Based on these functions, piezoelectric elements are widely used in numerous technical fields both as sensors and actuators, for example in medical technology, sonar applications, ultrasound technology, consumer electronics, mechanical engineering, the automotive industry and aerospace.

The state of the art describes numerous materials that are suitable as a basis for piezoelectrically active components.

For instance, DE 10 2019 135 245 B9 discloses a piezoelectric composition comprising silver and an oxide, wherein the oxide has a perovskite structure and is represented at least in part by the formula x[BiₘFeO₃]-y[BaₙTiO₃].

The most common piezoelectric materials today are produced on the basis of the ferroelectric crystal lead zirconate titanate Pb(ZrₓTi₍₁₋ₓ₎)O₃ (PZT), which, like the similar barium titanate, usually has a perovskite structure. Perovskite refers to the general structure type of the close-packed ionic structure ABX₃, where A and B are cations and X is the anion. Distortions in the perovskite structure can cause polarization and thus dipole formation in the crystal lattice, which is the cause of the piezoelectric properties of many perovskites. For example, in lead zirconate titanate (PZT) below the Curie temperature (T_{c}), the titanium ions in the ion lattice move out of their central position, resulting in a dipole lattice with piezoelectric properties.

However, the temperature range for the use of PZT is very limited. The maximum temperature at which PZT can be used permanently and while maintaining a sufficient piezoelectric coefficient (with a field and a change in length along the poling axis (longitudinal effect)) d₃₃ of more than 50 pC/N is usually around 250° C.

To solve this problem, a material with improved piezoelectric functionality at high temperatures is described in WO 2019/243778 A1, US 2013/0207020 A1 and US 2018/0315916 A1, where the perovskitic material (BiₐK₁₋ₐ)TiO_{3-y}BiFeO₃—PbTiO₃ (or in alternative formula notation KₓBi_{y}Pb₂FeᵥTi_{w}O₃ with x+y+z=1.0 and v+w=1.0) serves as the material basis.

As part of the production of (BiₐK₁₋ₐ)TiO_{3-y}BiFeO₃—PbTiO₃ in WO 2019/243778 A1, US 2013/0207020 A1 and US 2018/0315916 A1, in addition to Bi₂O₃, Fe₂O₃ and TiO₂, PbO is weighed and mixed as the lead component and K₂CO₃ as the potassium component.

Potassium carbonate (K₂CO₃) is highly hygroscopic and has a water solubility at 25° C. of L=1120 g/l, whereas alternative potassium compounds are typically also hygroscopic and water soluble (e.g. KOH: L=1130 g/l; KNO₃: L=316 g/l; K₂C₂O₄: L=360 g/l; K₂CO₃: L=1120 g/l; KCl: L=347 g/l, each at 25° C.). These properties pose major challenges for the manufacturing process of the piezoceramic material from the following aspects:

The pronounced hygroscopicity of the potassium compounds leads to the constant absorption of humidity and makes it difficult to weigh the exact and constant quantity of reactant, which can have a particularly negative impact on the quality of the products and the reproducibility of the manufacturing process unless controlled ambient conditions are ensured at considerable cost and effort.

The high water solubility of the potassium compounds also requires mixing with organic, liquid, anhydrous media. Respective solvents, such as isopropyl alcohol, which is used in US 2013/0207020 A1 and US 2018/0315916 A1, are flammable. Complex safety precautions are therefore necessary, particularly with respect to the upscaling of the manufacturing process. Nevertheless, it is desirable to minimize the use of organic solvents in the manufacturing process, not least for environmental reasons.

The publication EP 3 331 840 A1 describes a process in which the starting material is homogenized in an aqueous suspension and then subjected to spray freeze granulation in order to prevent water-soluble components, such as alkalis, from being dissolved out during subsequent processing and segregating during drying. In addition to the need for additional process steps, however, the process is not able to minimize inaccuracies in the weighing of the starting materials.

WO 2019/243778 A1 describes dry mixing without a liquid medium. However, this process is associated with considerable disadvantages, since the hygroscopic properties of the potassium compounds during feeding and during the actual dry mixing can lead to clumping and consequently unfavourable heterogeneous mixing distributions, which may reduce the quality of the materials obtained.

In view of the above, the objective of the invention is therefore to provide a compound and a material which are characterized by excellent piezoelectric functionality at high temperatures and at the same time can be provided in high quality and quantity using a simple, cost-effective and environmentally friendly process.

### SUMMARY

Therefore, as a solution to the above problems, the present invention provides a compound having a perovskite structure, characterized in that it has the basic composition AgₓBi_{y}M_{z}FeᵥN_{w}O₃, wherein x+y+z=0.9 to 1.1 and v+w=0.9 to 1.1, wherein M is selected from Pb and/or Ba, and wherein N is selected from Ti and/or Zr.

Furthermore, a material with piezoelectric functionality is provided, characterized in that it comprises perovskitic material containing the aforementioned compound.

Furthermore, the present invention provides a method for producing the aforementioned material with piezoelectric functionality.

Furthermore, a piezoelectric device is described, preferably comprising a piezoceramic body with at least two electrodes, which comprises the aforementioned compound with perovskite structure or the aforementioned material with piezoelectric functionality.

Advantageous embodiments of the invention can be seen from the following explanations.

### BRIEF DESCRIPTION OF THE DRAWINGS

The invention is described in more detail with reference to the accompanying drawings.

FIG. 1 shows an exemplary process for the production of piezoceramic materials according to the invention, and

FIGS. 2A and 2B represent ceramographic images of exemplary sintered compositions.

### DETAILED DESCRIPTION

The invention and its advantages are explained in more detail below with reference to preferred embodiments.

In one embodiment, the present invention relates to a compound having a perovskite structure, characterized in that the compound has the basic composition AgₓBi_{y}M_{z}FeᵥN_{w}O₃, wherein x+y+z=0.9 to 1.1 and v+w=0.9 to 1.1, wherein M is selected from Pb and/or Ba, preferably Pb or Ba, and wherein N is selected from Ti and/or Zr, preferably Ti or Zr.

In a preferred embodiment, M comprises both Pb and Ba, so that the compound has the basic composition AgₓBi_{y}(Pb,Ba)_{z}FeᵥN_{w}O₃ and z is the mass fraction of the sum of both metals in the basic composition.

In a further preferred embodiment, M represents Pb, so that the compound has the basic composition AgₓBi_{y}Pb_{z}FeᵥN_{w}O₃.

Preferably, the sum of x, y and z is 0.95 to 1.05, and the sum of v and w=0.95 to 1.05. Particularly preferably, x+y+z=1 and v+w=1. In general, x, y, z, v and w independently of one another satisfy 0<x<1, 0<y<1, 0<z<1, 0<v<1, and 0<w<1.

It has been found that silver compounds, which are characterized by relatively low water solubility and non-hygroscopic properties, are easy to handle and enable the production of materials with excellent piezoelectric properties at high temperatures.

In a preferred embodiment, x, y, z, v and w satisfy:

$$0.005 \leq x \leq 0.3$$

$$0.4 \leq y \leq 0.9$$

$$0.01 \leq z \leq 0.7$$

$$0.4 \leq v \leq 0.8$$

$$0.2 \leq w \leq 0.6 .$$

In a further preferred embodiment, x, y, z, v and w satisfy:

$$0.01 \leq x \leq 0.2$$

$$0.5 \leq y \leq 0.8$$

$$0.05 \leq z \leq 0.5$$

$$0.5 \leq v \leq 0.7$$

$$0.3 \leq w \leq 0.5 .$$

In a particularly preferred embodiment with regard to the piezoelectric properties (e.g. determined by T_{c} and d₃₃) in the high temperature range, x, y, z, v and w satisfy:

$$0.02 \leq x \leq 0.14$$

$$0.56 \leq y \leq 0.76$$

$$0.1 \leq z \leq 0.42$$

$$0.54 \leq v \leq 0.62$$

$$0.38 \leq w \leq 0.46 .$$

Perovskites are characterized by the general structure type of the close-packed ionic structure ABX₃, where A and B represent cations and X the anion. In this respect, it is preferred that in the compound according to the invention Ag and Bi (or Ag⁺ and Bi³⁺) occupy the position A in the underlying perovskitic basic structure ABO₃. Furthermore or alternatively, it is preferred that in the compound according to the invention Fe and Ti or Zr (or Fe³⁺ and Ti⁴⁺ or Zr⁴⁺) occupy position B in the underlying perovskitic basic structure ABO₃.

Typically, the compound according to the invention exhibits an orthorhombic/rhombohedral crystal structure.

The Goldschmidt tolerance factor t defines a lower tolerance limit depending on the ionic radii for the formation of the perovskite structure (see V. M. Goldschmidt: Die Gesetze der Krystallochemie. In: Die Naturwissenschaften, Vol. 14, No. 21, 1926, pp. 477-485). This also enables estimates to be made of the degree of distortion and statements to be made about the ratio of bond lengths. The compounds according to the invention preferably have a perovskite structure tolerance factor according to Goldschmidt t in the range from 0.820 to 0.880, more preferably in the range from 0.840 to 0.860. For the calculation of the Goldschmidt tolerance factor t according to the present invention, effective ionic radii according to R. D. Shannon; “Revised Effective Ionic Radii and Systematic Studies of Interatomic Distances in Halides and Chalcogenides”; Acta Crystallography; A32; 1976; 751-767 are used.

In a further embodiment, the present invention provides a material having piezoelectric functionality, characterized in that the material comprises perovskitic material containing the above-described compound having a perovskite structure.

Preferably, the total amount of non-perovskite phases present in the material is less than 10 wt %, more preferably less than 8 wt %, more preferably less than 5 wt %, still more preferably less than 2 wt %, still more preferably less than 1 wt %, most preferably less than 0.1 wt %. The amount of non-perovskite phases present in the ceramic may be a trace amount.

It is particularly preferable that the material consists of radiographically pure perovskite material without radiographically detectable non-perovskite foreign phases.

The perovskite material can also comprise one or more perovskite phases in addition to the basic composition AgₓBi_{y}M_{z}FeᵥN_{w}O₃ with x+y+z=0.9 to 1.1 and v+w=0.9 to 1.1. Additional perovskite phases may have rhombohedral or tetragonal crystal structures. It is preferred that the perovskite material does not comprise a perovskite phase with the formula (BiₐK₁₋ₐ)TiO₃ with 0.4≤a≤0.6. In further preferred embodiments, the perovskite material does not comprise potassium ions.

In the perovskitic material contained in the material, one or more of Ag, Bi, M, Fe and N can be replaced by a dopant, for example to modify the Curie temperature and/or the piezoelectric activity.

Dopants may be added in a suitable amount, for example in an amount of up to 2% by weight, preferably up to 1% by weight, in embodiments up to 50 atomic %, or up to 20 atomic %. It is further preferred that dopants are added in an amount of at least 0.001% by weight more preferably at least 0.005% by weight. The figures in % by weight refer to the total weight of the perovskite material.

Preferred dopants are metal dopants.

For example, a metal dopant can act as a substituent for the A-position in the underlying perovskitic base structure ABO₃ and replace Ag and/or Bi, for example. Preferably, the metal dopant for the A-position is selected from the group consisting of Li, Na, Ca, Sr, Ba and a rare earth metal. Doping with Li, Na, Ca, Sr or Ba at the A-position may reduce the dielectric loss, modify (e.g. increase) the Curie point and/or favourably influence the phase composition, while substitution with rare earth metals (such as La or Nd) may improve the piezoelectric activity.

The metal dopant can be a metal dopant for the B-position in the underlying perovskite base structure ABO₃ and can replace, for example, Fe and/or Ti.

Preferred dopants for the B-position can be selected, for example, from the group consisting of Ti, Zr, W, Nb, V, Ta, Mo and Mn. Preferred metal dopants for the B position can have a higher valence than the valence of the substituted metal, which increases the resistivity of the material and reduces its electrical conductivity. In a further preferred embodiment with regard to an improved reduction in insulation resistance and dielectric losses, the metal dopant for the B-position is Mn.

As mentioned above, the material according to the present invention is characterized by an advantageous piezoelectric functionality in the high temperature range (i.e. at working temperatures above 250° C. and typically up to at least 500° C.).

Preferably, the material according to the invention has a piezoelectric constant d₃₃ (with a field and a change in length along the poling axis (longitudinal effect)) of greater than 50 pC/N, further preferably greater than 60 pC/N, and particularly preferably greater than 70 pC/N, in each case determined in accordance with EN 50324. Typically, the piezoelectric constant d₃₃ is 50 pC/N to 110 pC/N, for example 60 to 100 pC/N.

Furthermore, the material is preferably suitable for permanent use at maximum working temperatures of at least 450° C., more preferably at least 500° C., and particularly preferably at least 550° C.

The Curie temperature T_{c} of the functional ceramics, which may be determined in accordance with EN 50324, is preferably at least 500° C., and more preferably 550° C. to 640° C.

The permittivity number E, defined as the ratio of the absolute permittivity of the material and the permittivity in a vacuum (ε₀=8.85-10⁻¹² F/m) is preferably 100 to 500, e.g. 180 to 340.

The dielectric loss factor tan δ of the material, which may be determined by small signal measurements, is preferably 0.05 or less, more preferably 0.04 or less, for example 0.01 to 0.03.

The invention also relates to a process for producing the above-described material with piezoelectric functionality, comprising:
(1) mixing a raw material combination comprising Ag, Bi, Pb and/or Ba, Fe, Ti and O and, if necessary, grinding the raw material combination;
(2) heat treatment of the mixed and optionally ground raw material combination to provide the perovskitic material with the basic composition AgₓBi_{y}M_{z}FeᵥTi_{w}O₃ with x+y+z=0.9 to 1.1 and v+w=0.9 to 1.1, wherein M is selected from Pb and/or Ba.

In a preferred embodiment, the raw material combination comprises Ag, Bi, Pb, Ba, Fe, Ti and O, such that M in the base composition comprises both Pb and Ba. In a further preferred embodiment, M is exclusively Pb.

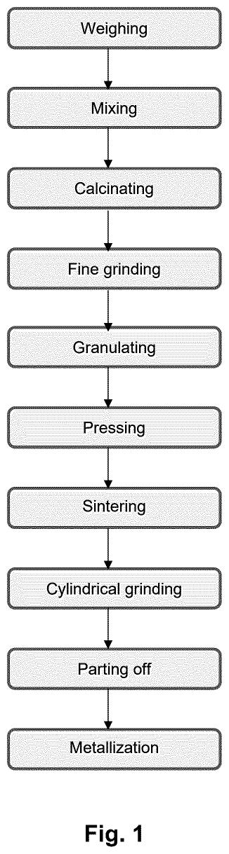

The manufacturing process according to the invention can comprise further process steps, as illustrated, for example, in FIG. 1.

In general, the process begins with the provision of the raw materials (possibly with dopants) and their weighing. The starting raw materials are not particularly restricted and may include oxides, carbonates, hydroxides, halides or other salts of the metals used. Preferably, the raw material combination comprises Bi₂O₃, Fe₂O₃, TiO₂ and PbTiO₃ and/or BaTiO₃, as well as one or more compounds selected from Ag₂O, AgF, AgCl, AgBr, AgI, AgNO₃, AgCNO, AgN₃, Ag₂S and AgOH. With regard to an advantageously low water solubility of the individual raw materials, the raw material combination comprises Bi₂O₃, Fe₂O₃, TiO₂ and PbTiO₃ and/or BaTiO₃, as well as one or more compounds selected from Ag₂O, AgCl, AgBr, AgI, AgCNO, AgN₃, Ag₂S and AgOH. In particularly preferred embodiments, Ag₂O is used as a silver-containing raw material (solubility in water at 25° C. L=0.025 g/l). Other raw materials (such as metal oxides, for example WO₃ or MoO₃) can be added if necessary, provided that they do not inhibit the formation of the perovskite structure with the composition AgₓBi_{y}M_{z}Fe_{z}N_{w}O₃ with x+y+z=0.9 to 1.1 and v+w=0.9 to 1.1.

In contrast to known processes which are dependent on the use of raw materials with pronounced hygroscopic properties (such as potassium compounds), the process according to the invention enables simple, constant and precise weighing of the raw materials and does not require any additional measures (e.g. pre-drying and/or weighing in a protective gas atmosphere).

The combination of raw materials is then mixed in a dry state or in a liquid medium and, if necessary, ground, whereby aqueous media (e.g. water) can advantageously be used as the liquid mixing and/or grinding medium. By minimizing or dispensing with the use of organic solvents, the environmental friendliness of the process can be improved, particularly in the upscaling of the production process, and the requirements for occupational and laboratory safety can be reduced without impairing product quality and consistency.

Calcination of the mixed and optionally ground raw material combination enables the provision of the perovskitic material with the composition AgₓBi_{y}M_{z}FeᵥN_{w}O₃ with x+y+z=0.9 to 1.1 and v+w=0.9 to 1.1, wherein M is selected from Pb and/or Ba, and wherein N is selected from Ti and/or Zr. It should be noted that calcination can be carried out either before or after grinding and that coarse and ultrafine grinding steps can also be interposed. The calcination conditions are not particularly restricted and can be suitably adjusted by the skilled person. Calcination is usually carried out at temperatures of higher than 600° C. to approximately 900° C.

Subsequent further processing of the calcinate obtained may be carried out according to known methods.

For example, the calcinate can be slurried in a liquid (preferably aqueous) medium and moulded into foils, which may be subsequently fed to a multilayer process (e.g. including printing, stacking, lamination and/or separation) before sintering of the material. Alternatively, the calcinate can be subjected to a “co-firing” process in which the foils are provided with electrodes in the green state, laminated to form a piezo element and then sintered together with the inner electrodes in a single process step, as described in DE 10234787 C1, for example. Another processing option is that the calcinate is slurried in a liquid, preferably aqueous, medium or plasticized and homogenized with a suitable binder and then processed by spray granulation and subsequent compression moulding before the moulded material is sintered. Alternatively, the calcinate may be finely ground and then granulated and compression moulded (as shown in FIG. 1).

The sintering conditions are not particularly restricted and may be suitably selected by the skilled person. Sintering is usually carried out at temperatures of at least 850° C., preferably 950° C. or higher.

The sintered material may be subjected to mechanical processing (comprising, for example, grinding and/or cutting), contacting, polarization (e.g. by applying a DC electric field of about 2 to 10 kV/mm at temperatures of 20 to 150° C.) and electrical measurement to provide the piezoceramic material according to known methods.

A further embodiment of the present invention relates to a piezoelectric device comprising the above-described compound with perovskite structure or the above-described material with piezoelectric functionality.

The piezoelectric device can be a piezoelectric actuator, sensor or transformer.

Typically, the piezoelectric device comprises the compound according to the invention with a perovskite structure or the material according to the invention with piezoelectric functionality in a piezoceramic body, as well as at least two electrodes.

The piezoceramic body may be designed as a (usually mechanically-hydraulically pressed) moulded body, e.g. in the form of a disc, plate, rod, hemisphere or ring.

The piezoelectric material and/or the electrodes may be formed as stacked layer structures. A stacked piezoelectric device may have a plurality of internal electrode layers and a plurality of piezoelectric layers, wherein each electrode layer is alternately stacked or layered with a respective piezoelectric layer, wherein at least one of the plurality of piezoelectric layers comprises the compound with perovskite structure according to the invention or the material with piezoelectric functionality according to the invention. Furthermore, such stacked structures may comprise further layers as required, such as one or more buffer layers, substrate layers, conductive sections and/or insulating layers. The thickness and area of the piezoelectric layer as well as the number of layers may be selected according to the intended use of the stacked piezoelectric device.

In further embodiments, the piezoelectric device may comprise, for example, a driver circuit, a current monitoring circuit, a switching means, as disclosed in DE 102015101817 A1, for example.

The fields of application of the piezoelectric devices according to the invention are in no way limited and include ultrasonic cleaning, ultrasonic processing, sonar technology, sensor technology, actuator technology, material testing, medical diagnostics and therapy, automotive industry, aerospace, mechanical engineering, building services, ignition systems, consumer electronics and audio applications.

### EXAMPLES

Following the process steps schematically depicted in FIG. 1, various exemplary piezoelectric functional ceramics based on the perovskite composition AgₓBi_{y}Pb_{z}FeᵥTi_{w}O₃ with x+y+z=0.9 to 1.1 and v+w=0.9 to 1.1 were manufactured as test specimen discs with dimensions of 6.5 mm×1.0 mm (see Table 2). The individual compositions are shown in the following Table 1.

TABLE 1
Exemplary compositions and their Goldschmidt factors.

| | | Gold- | |
|---|---|---|---|
| | | Schmidt | Fraction of Ti |
| Exam- | | factor t | in B-position |
| ple | Composition | [a.u.] | of ABO₃ [%] |
| 1 | Ag_{0.1000}Bi_{0.6550}Pb_{0.245}Fe_{0.555}Ti_{0.445} | 0.85008 | 44.50 |
| 2 | Ag_{0.0685}Bi_{0.6815}Pb_{0.250}Fe_{0.613}Ti_{0.387} | 0.84984 | 38.70 |
| 3 | Ag_{0.1125}Bi_{0.6675}Pb_{0.220}Fe_{0.555}Ti_{0.445} | 0.84780 | 44.50 |
| 4 | Ag_{0.1000}Bi_{0.6900}Pb_{0.210}Fe_{0.585}Ti_{0.415} | 0.84698 | 41.50 |
| 5 | Ag_{0.0900}Bi_{0.7050}Pb_{0.205}Fe_{0.615}Ti_{0.385} | 0.84570 | 38.50 |
| 6 | Ag_{0.1125}Bi_{0.6975}Pb_{0.190}Fe_{0.585}Ti_{0.415} | 0.84469 | 41.50 |
| 7 | Ag_{0.1000}Bi_{0.7150}Pb_{0.185}Fe_{0.615}Ti_{0.385} | 0.84387 | 38.50 |
| 8 | Ag_{0.1125}Bi_{0.7275}Pb_{0.160}Fe_{0.615}Ti_{0.385} | 0.84158 | 38.50 |

For this purpose, the raw materials Ag₂O, Bi₂O₃, PbTiO₃, Fe₂O₃, und TiO₂ were weighed, mixed and ground for 4 hours in 1 l drums (in demineralized water; 4:1 mixture; ZrO₂ grinding beads). The particle diameters after grinding were determined using a laser granulometer at d₁₀=0.7 μm, d₅₀=1.5 μm and d₉₀=3.5 μm. The samples were dried for 24 h at 120° C. and granulated using a mesh sieve (500 μm). For calcination, the samples were filled into Al₂O₃ crucibles and calcined in air in a resistance furnace (60 min. at 200° C., 600 min. at 750° C. and 180 min. at 950° C.). The cooled samples were subjected to phase analysis via XRD, whereby the presence of non-perovskite foreign phases could be excluded. The calcinates were finely ground for 4 hours in 1 l drums (d₁₀=0.7 μm, d₅₀=1.5 μm and d₉₀=3.5 μm), dried for 24 h at 120° C. and sieved using a mesh sieve (500 μm) and then granulated after the addition of 0.8 wt. % PAF (bulk density d_{Bulk}=2.5 g/cm³). By means of uniaxial dry pressing (pressing force 34 kN), round cylinders with a diameter of 12 mm and a height of 30 mm and a bulk density of 5.2 g/cm³ were obtained. The compacts were then sintered according to the conditions listed in Table 1, ground round (d=6.5 mm) and sawn into discs (d=6.5 mm, h=1.0 mm). For the ceramographic analysis, the sintered discs were ground, polished and thermally treated for 2 h at 950° C. in a resistance furnace. The grain sizes in the ceramic microstructure were imaged by light microscopy and quantified by means of section line measurement and Saltykov analysis (see Table 2).

TABLE 2
Sintering conditions and specific grain size parameters
of the ceramic microstructures on sintered ceramics.

| | Sintering | Sintering | Sintering | Grain size parameters | | | |
|---|---|---|---|---|---|---|---|
| | temperature | time | density dₛᵢₙₜ | Mean | SD. | Maximum | Minimum |
| Sampl | [° C.] | [h] | [g/cm]³ | value [μm] | [μm] | [μm] | [μm] |
| A | 1000 | 3 | 7.89 | 1.08 | 0.13 | 1.27 | 0.88 |
| B | 1030 | 3 | 7.92 | 1.46 | 0.15 | 1.61 | 1.22 |
| C | 1050 | 3 | 7.87 | 2.08 | 0.18 | 2.27 | 1.78 |
| D | 1050 | 4 | 7.85 | 2.31 | 0.21 | 2.63 | 2.08 |
| E | 1060 | 3 | 7.83 | 3.17 | 0.28 | 3.48 | 2.78 |

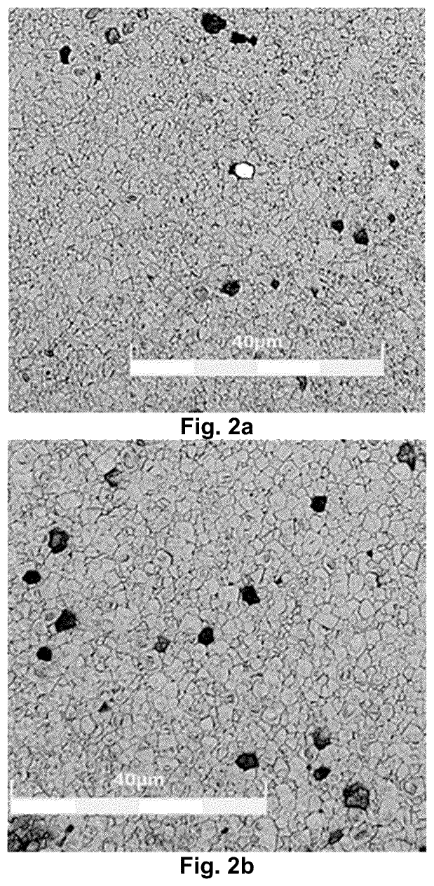

FIGS. 2a and 2b show examples of the ceramographic images of sintered samples B and C.

The samples were then coated with Ag paste and fired at 850° C. and, after cooling to room temperature, subjected to a polarization step (6.5 kV/mm for 15 min at 25° C. in oil).

The polarized materials (cylinders with the dimensions d=6.5 mm h=7.0 mm) were examined with respect to their piezoelectric and dielectric properties using an impedance analyzer. The results are summarized in Table 3.

TABLE 3
Dielectric and piezoelectric properties of the exemplary compositions.

| | | fₛ | tanδ | ε | K_{eff} | d₃₃ | T_{c} |
|---|---|---|---|---|---|---|---|
| Example | Composition | [kHz] | [*10]⁻³ | [a.u.] | [%] | [pC/N] | [° C.] |
| 1 | Ag_{0.1000}Bi_{0.6550}Pb_{0.245}Fe_{0.555}Ti_{0.445} | 229.5 | 20 | 304 | 47 | 100 | 600 |
| 2 | Ag_{0.0685}Bi_{0.6815}Pb_{0.250}Fe_{0.613}Ti_{0.387} | 230.7 | 20 | 269 | 41 | 77 | 650 |
| 3 | Ag_{0.1125}Bi_{0.6675}Pb_{0.220}Fe_{0.555}Ti_{0.445} | 237.4 | 20 | 338 | 39 | 86 | 550 |
| 4 | Ag_{0.1000}Bi_{0.6900}Pb_{0.210}Fe_{0.585}Ti_{0.415} | 237.4 | 15 | 294 | 38 | 78 | 570 |
| 5 | Ag_{0.0900}Bi_{0.7050}Pb_{0.205}Fe_{0.615}Ti_{0.385} | 236.5 | 15 | 267 | 38 | 74 | 640 |
| 6 | Ag_{0.1125}Bi_{0.6975}Pb_{0.190}Fe_{0.585}Ti_{0.415} | 237.4 | 15 | 304 | 38 | 81 | 600 |
| 7 | Ag_{0.1000}Bi_{0.7150}Pb_{0.185}Fe_{0.615}Ti_{0.385} | 237.5 | 30 | 272 | 37 | 74 | 610 |
| 8 | Ag_{0.1125}Bi_{0.7275}Pb_{0.160}Fe_{0.615}Ti_{0.385} | 238.6 | 33 | 293 | 35 | 73 | 620 |

fₛ: resonant frequency;
tanδ: dielectric loss factor;
ε: permittivity,
k_{eff}: effective coupling factor

The data shows that the materials according to the invention have an advantageously high piezoelectric constant d₃₃ (higher than 70 pC/N) in conjunction with high Curie temperatures T_{c} (550° C. to 650° C.).

To estimate the maximum working temperature, the thermal ageing stability of exemplary ceramics was tested in a further series of tests. For this purpose, the samples were aged at different temperature levels, starting at 300° C. for 20 h in each case, and it was determined up to which ageing temperature TA the piezoelectric constant d₃₃ of the samples (cylinders with dimensions d=6.5 mm and h=7.0 mm) is at least 60% of the initial value (determined at room temperature). The results of these ageing tests are listed in Table 4.

TABLE 4
Determination of the ageing temperature (min. 60 h thermal
treatment) as a function of the piezo coefficient d.₃₃

| | | T_{A} [° C.] | | | |
|---|---|---|---|---|---|
| Example | Composition | d₃₃ ≥ 90% | d₃₃ ≥ 80% | d₃₃ ≥ 70% | d₃₃ ≥ 60% |
| 9 | Ag_{0.1000}Bi_{0.7150}Pb_{0.185}Fe_{0.615}Ti_{0.385} | ~350 | ~450 | ~525 | ~550 |
| 10 | Ag_{0.0900}Bi_{0.7050}Pb_{0.205}Fe_{0.615}Ti_{0.385} | ~425 | ~475 | ~550 | ~560 |
| 11 | Ag_{0.1125}Bi_{0.6975}Pb_{0.190}Fe_{0.585}Ti_{0.415} | ~425 | ~475 | ~525 | ~540 |
| 12 | Ag_{0.0685}Bi_{0.6815}Pb_{0.250}Fe_{0.613}Ti_{0.387} | ~550 | ~575 | ~575 | ~580 |
| 13 | Ag_{0.1000}Bi_{0.6550}Pb_{0.245}Fe_{0.555}Ti_{0.445} | ~475 | ~500 | ~540 | ~570 |

The obtained data shows that the perovskitic compounds according to the present invention enable the provision of functional ceramics with excellent piezoelectric and dielectric properties at high temperatures.

1-15. (canceled)

16. A compound having a perovskite structure, comprising:
a basic composition AgₓBi_{y}M_{z}FeᵥN_{w}O₃, wherein x+y+z=0.9 to 1.1 and v+W=0.9 to 1.1, wherein M is selected from Pb and/or Ba, wherein N is selected from Ti and/or Zr, and
wherein x, y, z, v and w satisfy:
$$0.01 \leq x \leq 0.2$$
$$0.5 \leq y \leq 0.8$$
$$0.05 \leq z \leq 0.5$$
$$0.5 \leq v \leq 0.7$$
$$0.3 \leq w \leq 0.5 .$$

17. The compound having a perovskite structure according to claim 16, wherein x, y, z, v and w satisfy:
$$0.02 \leq x \leq 0.14$$
$$0.56 \leq y \leq 0.76$$
$$0.1 \leq z \leq 0.42$$
$$0.54 \leq v \leq 0.62$$
$$0.38 \leq w \leq 0.46 .$$

18. The compound having a perovskite structure according to claim 16, wherein Ag⁺ and Bi³⁺ occupy position A in an underlying perovskite base structure ABO₃.

19. The compound having a perovskite structure according to claim 16, wherein Fe³⁺ and Ti⁴⁺ occupy position B in an underlying perovskite base structure ABO₃.

20. A material with piezoelectric functionality, the material comprising a perovskitic material containing the compound according to claim 16.

21. The material according to claim 20, wherein the material consists of radiographically pure perovskitic material without radiographically detectable non-perovskite foreign phases.

22. The material according to any one of claim 20, wherein the perovskitic material does not comprise a perovskite phase having a formula (BiₐK₁₋ₐ)TiO₃ with 0.4≤a≤0.6, and wherein the perovskitic material does not comprise potassium ions.

23. The material according to claim 20, wherein the perovskitic material is doped with manganese (Mn).

24. The material according to claim 20, wherein the material has a piezoelectric constant d₃₃ (at a field and a change in length along a poling axis (longitudinal effect)) at working temperatures of up to 500° C. of greater than 50 pC/N.

25. A method of manufacturing a material with piezoelectric functionality according to claim 20, comprising:
(1) mixing a raw material combination comprising Ag, Bi, Pb and/or Ba, Fe, Ti and/or Zr, and O, and optionally grinding the raw material combination;
(2) heat treating the mixed and optionally milled raw material combination to provide the perovskitic material having the composition AgₓBi_{y}M_{z}FeᵥN_{w}O₃, wherein x+y+z=0.9 to 1.1 and v+w=0.9 to 1.1, and wherein M is selected from Pb and/or Ba, wherein N is selected from Ti and/or Zr, and
wherein x, y, z, v and w satisfy:
$$0.01 \leq x \leq 0.2$$
$$0.5 \leq y \leq 0.8$$
$$0.05 \leq z \leq 0.5$$
$$0.5 \leq v \leq 0.7$$
$$0.3 \leq w \leq 0.5 .$$

26. The method according to claim 25, wherein in step (1) an aqueous medium and water is used as mixing and/or grinding medium.

27. The method according to claim 25, wherein the raw material combination comprises Bi₂O₃, Fe₂O₃, TiO₂ and/or ZrO₂, and PbTiO₃ and/or BaTiO₃, and one or more compounds selected from Ag₂O, AgF, AgCl, AgBr, AgI, AgNO₃, AgCNO, AgN₃, Ag₂S and AgOH.

28. A piezoelectric device, comprising a compound with a perovskite structure, comprising:
a basic composition AgₓBi_{y}M_{z}FeᵥN_{w}O₃, wherein x+y+z=0.9 to 1.1 and v+W=0.9 to 1.1, wherein M is selected from Pb and/or Ba, wherein N is selected from Ti and/or Zr, and
wherein x, y, z, v and w satisfy:
$$0.01 \leq x \leq 0.2$$
$$0.5 \leq y \leq 0.8$$
$$0.05 \leq z \leq 0.5$$
$$0.5 \leq v \leq 0.7$$
$$0.3 \leq w \leq 0.5 ,$$
or
a material with piezoelectric functionality comprising a perovskitic material containing the compound, and
a piezoceramic body with at least two electrodes.
